(19) United States
(12) Patent Application Publication
(10) Pub. No.: US 2016/0291380 A1
(43) Pub. Date: Oct. 6, 2016

(54) LIQUID CRYSTAL DISPLAY AND MANUFACTURING METHOD THEREOF

(71) Applicant: Samsung Display Co., Ltd., Yongin-si (KR)

(72) Inventors: Seok-Joon HONG, Seongnam-si (KR); Dae Ho SONG, Hwaseong-si (KR); Sang Il PARK, Seoul (KR); Ji Yeon CHOI, Yongin-si (KR)

(21) Appl. No.: 14/869,761

(22) Filed: Sep. 29, 2015

(30) Foreign Application Priority Data
Mar. 31, 2015 (KR) 10-2015-0045224

(51) Int. Cl. G02F 1/1345; G02F 1/1368; G02F 1/1333; H01L 27/12

(52) U.S. Cl. CPC G02F 1/13454; H01L 27/1259; H01L 27/124; H01L 27/1248; G02F 1/1368; G02F 1/133345; G02F 1/133377

(57) ABSTRACT

A liquid crystal display (LCD) includes: a substrate including a display area and a peripheral area; a thin film transistor disposed on the display area of the substrate; a pixel electrode connected to the thin film transistor; a liquid crystal layer disposed inside a microcavity on the pixel electrode; a roof layer disposed on the microcavity; a gate driver integrated on the peripheral area of the substrate and including a plurality of signal lines and a plurality of stages connected to the plurality of signal lines via contact holes; and a blocking layer comprising a base layer disposed on the contact hole and a first inorganic layer disposed on the base layer.

### CROSS-REFERENCE TO RELATED APPLICATION

This application claims priority to and the benefit of Korean Patent Application No. 10-2015-0045224 filed in the Korean Intellectual Property Office on Mar. 31, 2015, the disclosure of which is incorporated herein by reference in its entirety.

### BACKGROUND

(a) Technical Field

The present disclosure relates to a liquid crystal display (LCD) and a manufacturing method thereof.

(b) Description of the Related Art

A liquid crystal display (LCD) is presently one of the most widely used display devices. The LCD includes a liquid crystal display panel in which a liquid crystal layer is formed between a lower display substrate and an upper display substrate that face each other. The LCD displays an image by applying voltages to a pixel electrode and a common electrode of the LCD panel, generating an electric field, changing arrangements of liquid crystal molecules of the liquid crystal layer by the generated electric field, and controlling polarization of incident light.

Various components are formed on the lower and upper display substrates of the LCD panel. For example, on the lower display substrate, a gate line for transmitting a gate signal, a data line for transmitting a data signal, a thin film transistor connected to the gate and data lines, a pixel electrode connected to the thin film transistor, and the like are formed. On the upper display substrate, a light blocking member, a color filter, a common electrode, and the like are formed. One or more of the components formed on the upper display substrate may be formed on the lower display substrate. A gate driver may be patterned together with the data line, the gate line, the thin film transistor, and the like that are integrated on the lower display substrate. The integrated gate driver includes a plurality of stages for generating a gate voltage, such as a gate-on voltage, and may generate a gate voltage of various waveforms according to a clock signal, a carry signal, and the like that are input at each of the stages.

In a conventional LCD, two sheets of substrates are used for the lower and upper display substrates, and processes for forming and assembling the aforementioned components are required. As a result, the LCD panel becomes heavy, thick, and costly while requiring a long processing time to manufacture it. Recently, a technique for manufacturing an LCD by forming a plurality of microcavities on a single substrate as a tunnel-shaped structure, injecting liquid crystals into the structure, and then sealing the structure with a capping layer has been developed. In this case, the gate driver integrated on the substrate is covered by the capping layer. However, moisture may permeate via the capping layer, and the permeated moisture may cause corrosion or a defect to a gate driver circuit.

The above information disclosed in this Background section is only to enhance the understanding of the background of the present disclosure, therefore it may contain information that is not known to a person of ordinary skill in the art.

### SUMMARY

The present disclosure has been made in an effort to provide a liquid crystal display (LCD) and a manufacturing method thereof. A gate driver integrated into a display panel can be protected from an external environment. A liquid crystal layer is formed in a plurality of microcavities.

An LCD according to an exemplary embodiment of the present disclosure includes: a substrate including a display area and a peripheral area; a thin film transistor disposed on the display area of the substrate; a pixel electrode connected to the thin film transistor; a liquid crystal layer disposed inside a microcavity on the pixel electrode; a roof layer disposed on the microcavity; a gate driver integrated on the peripheral area of the substrate and including a plurality of signal lines and a plurality of stages connected to the plurality of signal lines via a contact hole; and a blocking layer comprising a base layer disposed on the contact hole and a first inorganic layer disposed on the base layer.

The base layer may be an organic layer or a liquid crystal layer.

The liquid crystal display may further comprise a lower insulating layer disposed between the microcavity and the roof layer in the display area. The first inorganic layer of the blocking layer may be formed as a same layer as the lower insulating layer.

The blocking layer may further comprise a roof layer disposed on the first inorganic layer. The roof layer of the blocking layer may be formed as a same layer as the roof layer of the display area.

The liquid crystal display may further comprise an upper insulating layer disposed on the roof layer in the display area. The blocking layer may further comprise a second inorganic layer that is disposed on the roof layer and is formed as a same layer as the upper insulating layer.

The liquid crystal display may further comprise a common electrode disposed between the microcavity and the roof layer in the display area. The blocking layer may further comprise a conductive layer that is formed between the base layer and the inorganic layer and as a same layer as the common electrode.

The blocking layer may be disposed to overlap and cover the contact holes.

The blocking layer may be formed to entirely or partially cover the gate driver.

The base layer of the blocking layer may have a substantially same size as the microcavity of the display area.

According to an exemplary embodiment of the present disclosure, a method for providing an LCD is provided. The method comprises: forming a thin film transistor in a display area of a substrate; forming a gate driver including a signal line of a gate driver and a stage in a peripheral area of the substrate; forming at least one passivation layer on the thin film transistor, the signal line of the gate driver, and the stage; forming, in the display area, a pixel electrode connected to the thin film transistor via a contact hole formed in the at least one passivation layer; forming, in the peripheral area, a bridge for interconnecting the signal line and the stage via contact holes formed in the at least one passivation layer; forming a first sacrificial layer on the pixel electrode of the display area and a second sacrificial layer on the contact holes of the peripheral area; forming a lower insulating layer on the first sacrificial layer and the second sacrificial layer; and forming, on the lower insulating layer, a roof layer overlapping the first sacrificial layer and the second sacrificial layer.

The method may further comprise forming, on the roof layer, an upper insulating layer overlapping the first sacrificial layer and the second sacrificial layer.

The method may further comprise forming a common electrode on the first sacrificial layer and the second sacrificial layer.

The method may further comprise removing the first sacrificial layer to form a microcavity and forming a liquid crystal layer inside the microcavity in the display area.

The method may further comprise simultaneously removing the first sacrificial layer and the second sacrificial layer to form a microcavity and forming a liquid crystal layer inside the microcavity formed in the peripheral area.

The second sacrificial layer may not be removed when removing the first sacrificial layer.

According to the exemplary embodiment of the present disclosure, the gate driver integrated on the display panel can be prevented from becoming corroded or damaged by the external environment such as moisture, oxygen, etc. Since the layers that are included in the blocking layer and protect the gate driver can be formed together when forming the components of the display area, an additional process or cost for forming the blocking layer is not required.

### BRIEF DESCRIPTION OF THE DRAWINGS

FIG. 1 is a top plan view of a liquid crystal display (LCD), according to an exemplary embodiment of the present disclosure.

FIG. 2 is a top plan view illustrating region A in FIG. 1.

FIG. 3 is a cross-sectional view of a vicinity of a gate driver in FIG. 1.

FIGS. 4, 5, and 6 are cross-sectional views of vicinities of a gate driver of an LCD, according to some exemplary embodiments of the present disclosure.

FIG. 7 is a top plan view of four adjacent pixel areas in an LCD, according to the exemplary embodiment of the present disclosure.

FIG. 8 is a cross-sectional view of FIG. 7 taken along the line VIII-VIII.

FIG. 9 is a cross-sectional view of FIG. 7 taken along the line IX-IX.

FIGS. 10 to 28 are process cross-sectional views illustrating a manufacturing method of an LCD, according to an exemplary embodiment of the present disclosure.

### DETAILED DESCRIPTION OF THE EMBODIMENTS

The present disclosure will be described more fully hereinafter with reference to the accompanying drawings, in which exemplary embodiments of the present disclosure are shown. As those skilled in the art would realize, the described embodiments may be modified in various different ways without departing from the spirit or scope of the present disclosure.

Like reference numerals designate like elements throughout the specification. It will be understood that when an element such as a layer, film, region, or substrate is referred to as being “on” another element, it can be directly on the other element or intervening elements may be present. In contrast, when an element is referred to as being “directly on” another element, there may be no intervening elements present.

A liquid crystal display (LCD) according to an exemplary embodiment of the present disclosure and a manufacturing method thereof will be described in detail with reference to the drawings.

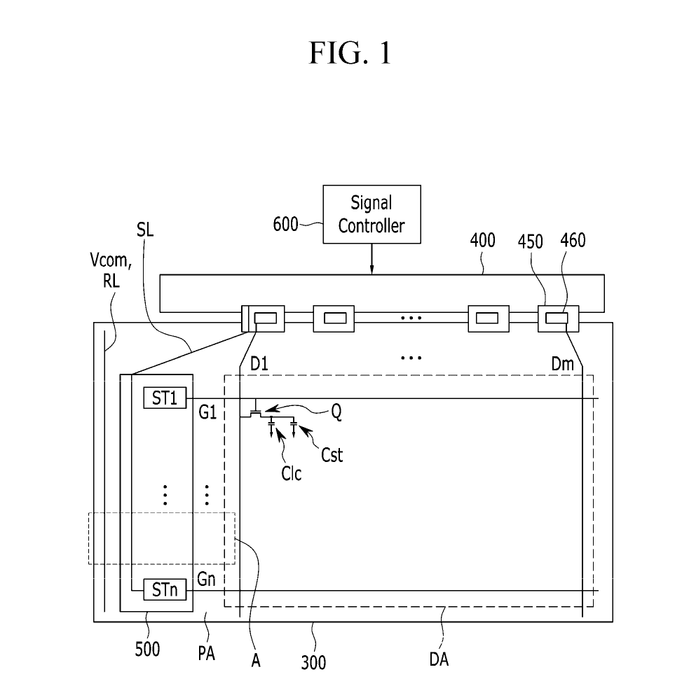

FIG. 1 is a top plan view of an LCD, according to an exemplary embodiment of the present disclosure. A display panel 300 includes a display area DA for displaying an image and a peripheral area PA around the display area DA where a gate driver 500 for applying a gate voltage to gate lines G1 to Gn and the like is disposed.

Data lines D1 to Dm of the display area DA receive a data voltage from a data driver 460 that is formed on a flexible printed circuit board (FPCB) 450 that is attached to the display panel 300. The data driver 460 may be an integrated circuit (IC). The gate driver 500 and the data driver 460 are controlled by a signal controller 600. A printed circuit board 400 is disposed outward from the FPCB 450 to transmit signals from the signal controller 600 to the data driver 460 and the gate driver 500. The signals provided to the gate driver 500 from the signal controller 600 include, but are not limited to, a start pulse vertical signal STV, clock signals CKV and CKVB, and a signal that provides a low voltage VSS of a specific level. In some exemplary embodiments, a smaller or larger number of start pulse vertical signals and/or clock signals may be included, and they may have two kinds of low voltages.

The display area DA includes a thin film transistor, a liquid crystal capacitor, a storage capacitor, and the like. The liquid crystal capacitor is formed by a liquid crystal layer including liquid crystal molecules that are filled in a microcavity (not shown). A plurality of gate lines G1 to Gn and a plurality of data lines D1 to Dm are disposed in the display area DA, and the gate lines G1 to Gn and the data lines D1 to Dm cross each other while being insulated from each other.

Each pixel includes a thin film transistor Q, a liquid crystal capacitor Clc, and a storage capacitor Cst. A control terminal of the thin film transistor Q is connected to one gate line, an input terminal of the thin film transistor Q is connected to one data line, and an output terminal of the thin film transistor Q is connected to one terminal of the liquid crystal capacitor Clc and one terminal of the storage capacitor Cst. The other terminal of the liquid crystal capacitor Clc is connected to a common electrode, and the other terminal of the storage capacitor Cst receives a storage voltage that may be generated by the signal controller 600. The pixel of the LCD panel may have an additional structure, in addition to the exemplary structure illustrated in FIG. 1.

The data lines D1 to Dm receive the data voltage from the data driver 460, while the gate lines G1 to Gn receive the gate voltage from the gate driver 500. The data driver 460 may be disposed in an upper or a lower part of the display panel 100 to be connected to the data lines D1 to Dm that extend in a vertical direction. In the exemplary embodiment of FIG. 1, the data driver 460 is disposed in the upper part of the display panel 300.

The gate driver 500 receives the start pulse vertical signal STV, the clock signals CKV and CKVB, and the low voltage VSS, generates gate voltages (gate-on and gate-off voltages), and applies the gate voltages to the gate lines G1 to Gn. The gate driver 500 includes a plurality of stages ST for generating and outputting the gate voltages based on the received signals, and a plurality of signal lines SL for transmitting the received signals to the stages ST. The signal lines SL may be disposed more outward from the display area DA than the stages ST. Though illustrated as a single line in FIG. 1, the signal line SL may include signal lines that correspond to the number of signals applied to the gate driver 500, or may include a larger or smaller number of signal lines than the number of signals.

The start pulse vertical signal STV, the clock signals CKV and CKVB, and the low voltage VSS are applied to the gate driver 500 via the FPCB 450 that is disposed proximate to the gate driver 500. These signals are transmitted to the FPCB 450 from an external source or a signal controller 600 via the PCB 400.

The gate driver 500 may be disposed in the peripheral area PA, for example, to the left, to the right, or to the left and right of the display area DA. A common voltage line Vcom may be disposed in the peripheral area PA around the gate driver 500 to transmit a common voltage to the common electrode of the display area DA. A repair line RL may also be disposed in the peripheral area PA. The repair line RL may instead be used, for example, to transmit the signal when the data line and the like are broken and cause a defect.

So far, an overall structure of the display device has been discussed. A structure of the gate driver 500 will now be described in more detail.

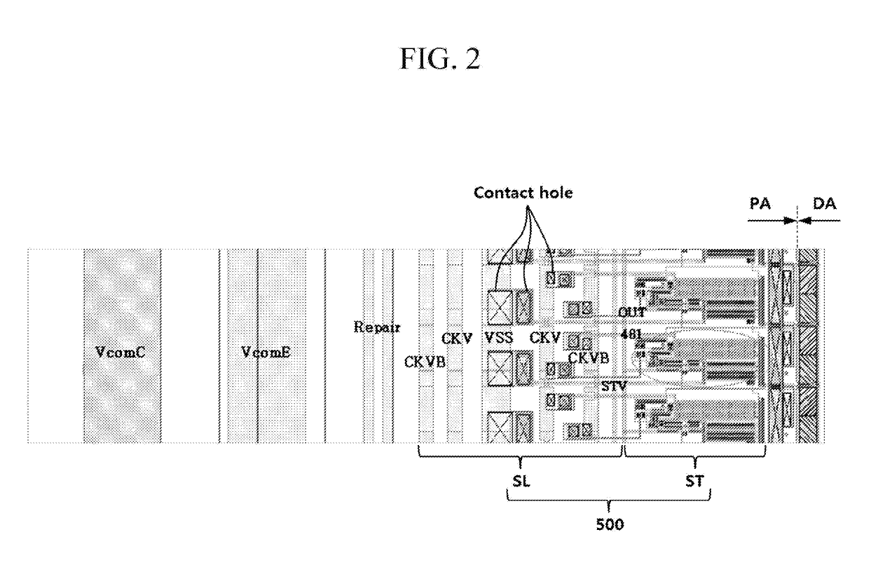

FIG. 2 is a top plan view illustrating a region A in FIG. 1. The region A corresponds to some of the peripheral area PA to the left of display area DA in FIG. 1. The signal line SL of the gate driver 500 (in the drawing, a signal transmitted by the signal line is marked) and roughly three stages ST are illustrated in FIG. 2. The common voltage line Vcom and the repair line RL are also illustrated to the left of the gate driver 500.

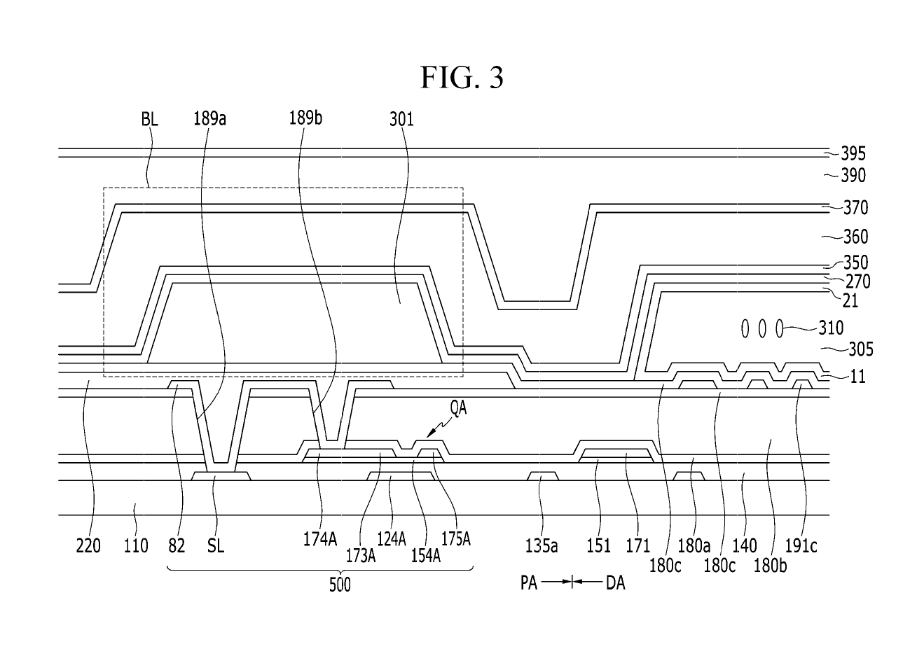

The signal line SL includes a plurality of signal lines for transmitting the start pulse vertical signal STV, the clock signals CKV and CKVB, the low voltage signal VSS, etc. The signal lines substantially extend in a vertical direction and are arranged to be parallel to each other. The stage ST includes a driving circuit including a plurality of thin film transistors. A passivation layer (refer to FIG. 3) is formed on the signal line SL and the driving circuit of the stage ST, and the signal line SL and the driving circuit of the stage ST are electrically connected via contact holes and a bridge that are formed in the passivation layer. In addition, the driving circuit of the stage ST and the gate lines G1 to Gn are also electrically connected via the contact holes and the bridge that are formed in the passivation layer. In some embodiments, the contact holes and the bridge may be formed inside the driving circuit to interconnect the thin film transistors.

A portion of the signal line SL and a portion of the driving circuit where the contact holes are formed are removed from the passivation layer above, so if moisture and the like may exist over the contact holes and permeate into the signal line SL and the driving circuit via the contact holes. Even if the bridge for the electrical connection blocks the contact holes, the moisture and the like may pass through the bridge and damage the signal lines and the driving circuit that are disposed below, and a characteristic of the bridge may deteriorate (such as an increase in resistance, occurrence of haze, etc.). An LCD including a structure that prevents permeation of the moisture and the like into a region of the gate driver 500 formed with the contact holes and protects a gate driver 500 from an external environment will now be described.

FIG. 3 is a cross-sectional view of a vicinity of the gate driver in FIG. 1. To simplify the drawing and clarify the present disclosure, a connection between one of a plurality of signal lines SL with one of a plurality of thin film transistors of a stage ST is exemplarily illustrated. A pixel of a display area DA is partially illustrated in FIG. 3 along with a gate driver of a peripheral area PA to describe a relationship therebetween.

A gate driver 500 is formed in the peripheral area PA. A gate driver 500 includes a signal line SL and a thin film transistor QA. The signal line SL and a gate electrode 124A of the thin film transistor QA is formed on a substrate 110, and a gate insulating layer 140 is formed thereon.

A semiconductor layer 154A, a source electrode 173A, and a drain electrode 175A of the thin film transistor QA are formed on the gate insulating layer 140. The source electrode 173A includes an extension 174A for connection with a different layer. First, second, and third passivation layers 180a, 180b, and 180c are formed on the source electrode 173A and the drain electrode 175A. One or two of the passivation layers 180a, 180b, and 180c may be omitted.

A first contact hole 189a is formed to partially expose the signal line SL after penetrating the passivation layers 180a, 180b, and 180c and the gate insulating layer 140. In addition, a second contact hole 189b is formed to partially expose the extension 174A of the source electrode 173A of the thin film transistor QA after penetrating the passivation layers 180a, 180b, and 180c. A bridge 82 is formed above the contact holes 189a and 189b and the third passivation layer 180c, and the bridge 82 electrically couples the signal line SL and the extension 174A. The bridge 82 may be made of a conductive material such as indium tin oxide (ITO), indium zinc oxide (IZO), etc. A light blocking member 220 may be disposed on the third passivation layer 180c and the bridge 82 to prevent light leakage or light reflection.

Even though the connection between the thin film transistor QA of the stage ST and the signal line SL is illustrated in FIG. 1, the signal line SL may be connected to other parts of a driving circuit of the stage ST via the contact holes and the bridge that are formed in the passivation layers 180a, 180b, and 180c, and the gate insulating layer 140. In addition, the signal line SL is illustrated to be formed on the same layer as the gate electrode 124A of the thin film transistor QA, but the signal line SL may be formed on a different layer, for example, on the same layer as the source electrode 173A and the drain electrode 175A.

A blocking layer BL including a plurality of layers is formed on the contact holes 189a and 189b and the bridge 82 that are disposed in the gate driver 500. The blocking layer BL is formed to overlap the contact holes 189a and 189b and cover the contact holes 189a and 189b. The blocking layer BL includes a base layer 301, a lower insulating layer 350, and a roof layer 360.

In one embodiment, the base layer 301 may be a part of a sacrificial layer that is used to form a microcavity 305 in the display area DA. In another embodiment, the microcavity is formed by the roof layer 360, and the base layer 301 may be a liquid crystal layer that is formed in the microcavity. In other words, the base layer 301 is formed by a remaining portion of the sacrificial layer, or by a liquid crystal layer that is injected into the microcavity after removal of the sacrificial layer. A size and shape of the blocking layer BL may be limited by the base layer 301. The sacrificial layer will be described later in relation to the pixel formed in the display area DA.

The lower insulating layer 350 is an inorganic layer that is disposed on the gate driver 500 of the peripheral area PA as an extended part of the lower insulating layer 350 of the display area DA. Such an inorganic layer may include silicon nitride (SiNₓ).

The roof layer 360 is an organic layer that is disposed on the gate driver 500 of the peripheral area PA as an extended part of the roof layer 360 of the display area DA. In some exemplary embodiments, the roof layer 360 may be an inorganic layer, and at least one of the lower insulating layer 350 and an upper insulating layer 370 may be omitted. A capping layer 390 is disposed on the roof layer 360, and a barrier layer 395 may be formed on the capping layer 390.

The blocking layer BL may further include an upper insulating layer 370 above the roof layer 360. The upper insulating layer 370 is an inorganic layer that is disposed on the gate driver 500 as an extend part of the upper insulating layer 370 disposed in the display area DA, and may include silicon nitride. The blocking layer BL may further include a common electrode 270 extended from the display area DA between the base layer 301 and the lower insulating layer 350. The blocking layer BL may include one, both, or neither of the upper insulating layer 370 and the common electrode 270, or may further include another inorganic or organic layer.

Since the blocking layer BL is formed on the contact holes 189a and 189b of the gate driver 500, as a composite layer including at least an organic layer and an inorganic layer or at least a liquid crystal layer and an inorganic layer, the contact holes 189a and 189b of the gate driver 500 can be protected from an external environment. Accordingly, moisture and the like cannot permeate via the contact holes 189a and 189b of the gate driver 500, thereby preventing degradation and enhancing the reliability of the gate driver 500.

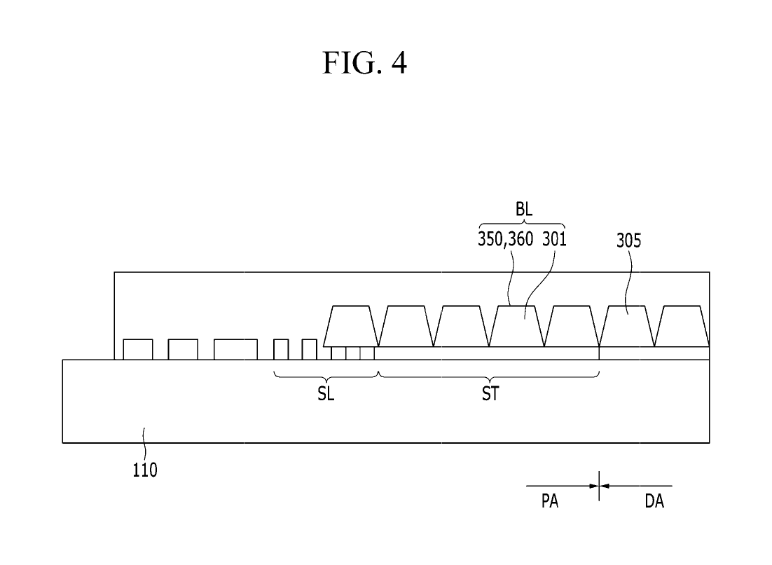

Shapes of a blocking layer BL according to exemplary embodiments of the present disclosure will now be described with reference to FIGS. 4, 5, and 6. FIGS. 4, 5, and 6 are cross-sectional views of vicinities of a gate driver of an LCD, according to some exemplary embodiments of the present disclosure. A blocking layer BL may be formed to have various shapes and protect the contact holes formed in the gate driver 500. The blocking layer BL may be formed to cover only a vicinity of the contact holes or to completely cover the gate driver 500. In FIGS. 4, 5, and 6, with respect to the shape of the blocking layer BL, some distinguishable components are schematically illustrated.

Since the blocking layer BL has a layered structure including a lower insulating layer 350, a roof layer 360, and the like, the base layer 301 may determine a shape of the blocking layer BL. Referring to FIG. 4, the base layer 301 of the blocking layer BL is formed to have substantially the same size as a microcavity 305 that corresponds to a liquid crystal layer of a display area DA (e.g., substantial congruence).

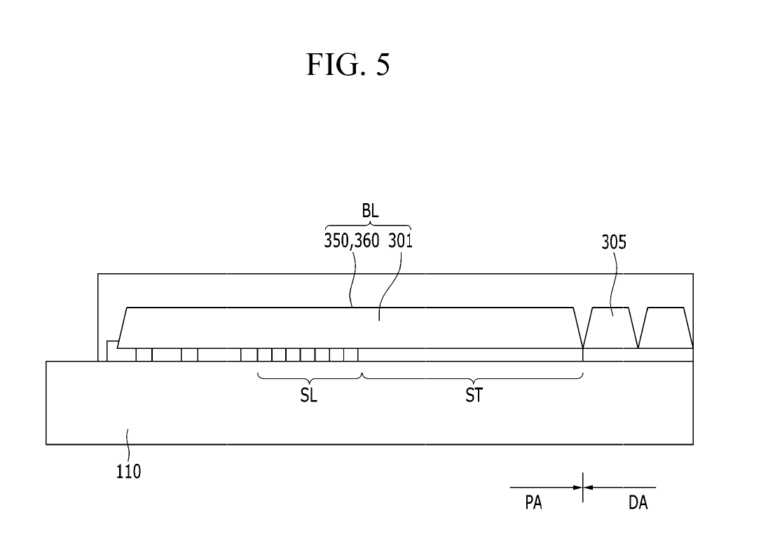

Referring to FIG. 5, the base layer 301 of the blocking layer BL is formed to be larger than the microcavity 305 of the display area DA. In this case, the base layer 301 may have a larger size than the microcavity 305 while having substantially the same height. The base layer 301 may be formed as a single pattern for covering an entire area of the gate driver 500, or may be formed as a plurality of patterns in a row direction and/or a column direction.

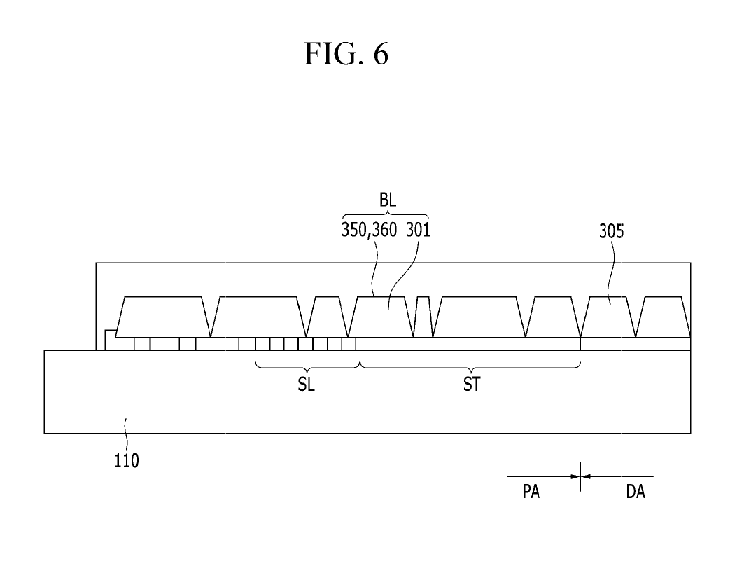

Referring to FIG. 6, the base layer 301 is formed to have various sizes and shapes, cover and protect the contact holes of the gate driver 500 according to the positions of contact holes.

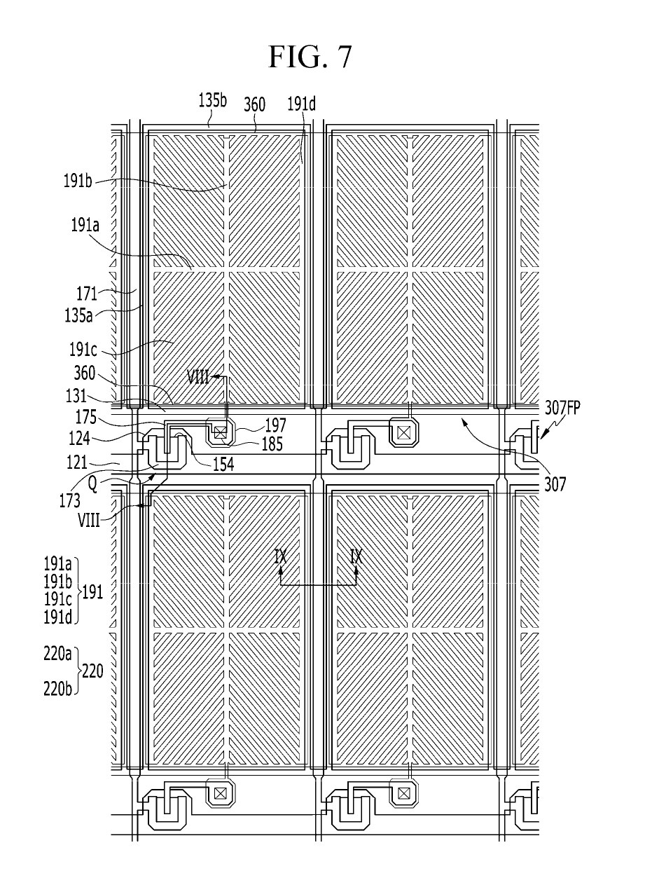

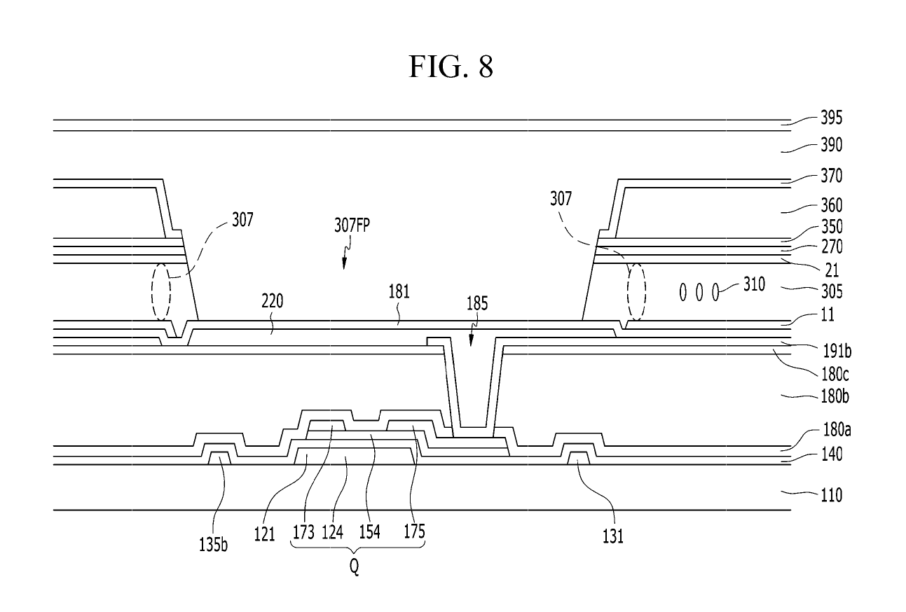

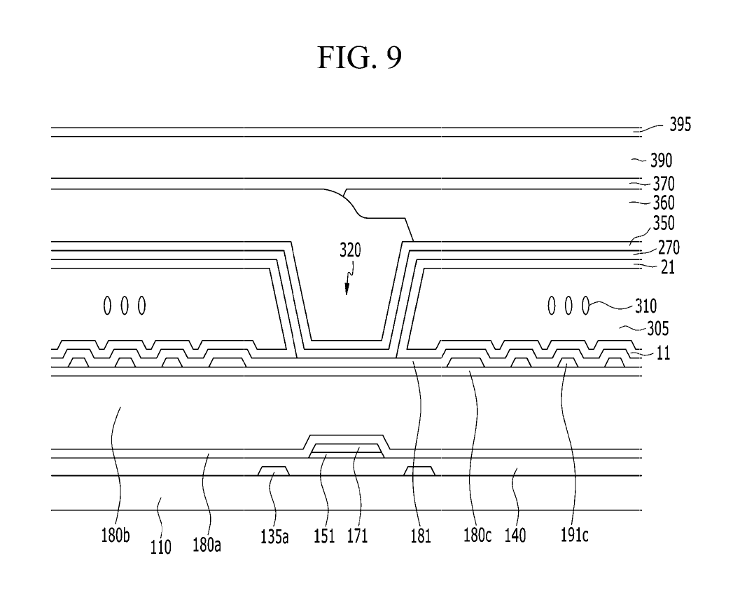

Components of the LCD in the display area DA will now be described in detail with reference to FIGS. 7, 8, and 9. FIG. 7 is a top plan view of four adjacent pixel areas in an LCD, according to the exemplary embodiment of the present disclosure, FIG. 8 is a cross-sectional view of FIG. 7 taken along the line VIII-VIII, and FIG. 9 is a cross-sectional view of FIG. 7 taken along the line IX-IX.

FIG. 7 illustrates a 2×2 pixel area that is a center part of a plurality of pixels areas, and such pixel areas may be vertically and horizontally repeated in the LCD.

A gate line 121 and a storage electrode line 131 are formed on a substrate 110 that is made of transparent glass or plastic. The gate line 121 includes a gate electrode 124. The storage electrode line 131 substantially extends in a horizontal direction and transmits a predetermined voltage such as a common voltage or the like. The storage electrode line 131 includes a pair of vertical portions 135a extending substantially perpendicular to the gate line 121, and a horizontal portion 135b interconnecting ends of the pair of vertical portions 135a. The vertical portion 135a and the horizontal portion 135b form a structure for enclosing a pixel electrode 191.

A gate insulating layer 140 is formed on the gate line 121 and the storage electrode line 131. A semiconductor layer 151 that is disposed below a data line 171 and a semiconductor layer 154 that is disposed under source and drain electrodes and in a channel of a thin film transistor Q are formed on the gate insulating layer 140. Ohmic contacts (not shown) may be formed between the respective semiconductor layers 151 and 154 and the data line 171 and between the source and drain electrodes.

Data conductors 171, 173, and 175 including the source electrode 173, the data line 171 that is connected to the source electrode 173, and the drain electrode 175 are formed on the semiconductor layers 151 and 154 and the gate insulating layer 140. The gate electrode 124, the source electrode 173, and the drain electrode 175 form a thin film transistor Q along with the semiconductor layer 154, and the channel of the thin film transistor Q is formed at a portion between the source and drain electrodes 173 and 175 of the semiconductor layer 154.

A first passivation layer 180a is formed on the exposed semiconductor layer 154 that is not covered by the data conductors 171, 173, and 175, the source electrode 173, and the drain electrode 175. The first passivation layer 180a may be made of an inorganic material such as silicon nitride (SiNₓ) and silicon oxide (SiOₓ).

A second passivation layer 180b and a third passivation layer 180c may be disposed on the first passivation layer 180a. The second passivation layer 180b may be made of an organic material, and the third passivation layer 180c may include an inorganic material such as silicon nitride (SiNₓ) and silicon oxide (SiOₓ). One or two of the first, second, and third passivation layers 180a, 180b, and 180c may be omitted.

A contact hole 185 may be formed by penetrating the first, second, and third passivation layers 180a, 180b, and 180c. The pixel electrode 191 that is disposed on the drain electrode 175 and the third passivation layer 180c may be electrically and physically connected via the contact hole 185. The pixel electrode 191 will now be described in detail.

The pixel electrode 191 may be made of a transparent conductive material such as ITO or IZO. The pixel electrode 191 has a quadrangular shape, and includes a cross-shaped stem portion having a horizontal stem portion 191a and a vertical stem portion 191b perpendicular thereto. In addition, the pixel electrode is divided into four sub-regions by the horizontal stem portion 191a and the vertical stem portion 191b, and each sub-region includes a plurality of minute branch portions 191c. In addition, in the current exemplary embodiment, the pixel electrode 191 further includes an outer stem portion 191d to interconnect the minute branch portions 191c at left and right edges of the pixel electrode 191. The outer stem portion 191d may be further extended above or below the pixel electrode 191.

The minute branch portions 191c of the pixel electrode 191 form an angle of approximately 40° to 45° with the gate line 121 or the horizontal stem portion 191a. The minute branch portions 191c of two neighboring sub-regions may be perpendicular to each other. In addition, widths of the minute branch portions may gradually become wider, or intervals between the minute branch portions 191c may be varied.

The pixel electrode 191 includes an extension 197 that is connected to a lower end of the vertical stem portion 191b and has a larger size than the vertical stem portion 191b. The pixel electrode 191 is physically and electrically connected to the drain electrode 175 through the contact hole 185 in the extension 197 and receives a data voltage from the drain electrode 175.

The above description of the thin film transistor Q and the pixel electrode 191 are only an example, so a structure of the thin film transistor and a design of the pixel electrode may be variously modified to improve the characteristics of the LCD including, but not limited to, side visibility and the like.

A light blocking member 220 is disposed to cover a region where the thin film transistor Q is formed on the pixel electrode 191. The light blocking member 220, according to the current exemplary embodiment, may be formed along a direction in which the gate line 121 extends. The light blocking member 220 may be made of a material that can block light.

An insulating layer 181 may be formed on the light blocking member 220, and the insulating layer 181 may be formed to cover the light blocking member 220 and to be extended above the pixel electrode 191. The insulating layer 181 may be made of silicon nitride or silicon oxide.

A lower alignment layer 11 is formed on the pixel electrode 191, and the lower alignment layer 11 may be a vertical alignment layer. The lower alignment layer 11 may be formed to include at least one of the materials that are generally used in the liquid crystal layer, such as polyamic acid, polysiloxane, polyimide, etc. The lower alignment layer 11 may be a photoalignment layer.

An upper alignment layer 21 is disposed to face the lower alignment layer 11, and a microcavity 305 is formed between the lower and upper alignment layers 11 and 21. A liquid crystal material including liquid crystal molecules 310 is injected into the microcavity 305 to form a liquid crystal layer. The microcavity 305 may be formed along a column direction of the pixel electrode 191, that is, along a vertical direction. In the current exemplary embodiment, an aligning material for forming the alignment layers 11 and 21 and a liquid crystal material including the liquid crystal molecules 310 may be injected into the microcavity 305 using a capillary force, and the microcavity 305 includes an injection hole 307 for such injection. On the other hand, the lower and upper alignment layers 11 and 21 are distinguishable only by their positions and may be connected to each other, or may be formed simultaneously.

The microcavity 305 is vertically divided by a plurality of injection areas 307FP that is disposed to overlap the gate line 121 to form a plurality of microcavities, and a plurality of microcavities 305 may be formed along a column direction of the pixel electrode 191, i.e., along a vertical direction. Further, the microcavity 305 is divided by a partition wall portion 320 to be described later to form a plurality of microcavities 305, and the plurality of microcavities 305 may be formed along the row direction of the pixel electrode 191, i.e., along the horizontal direction in which the gate line 121 extends. A multitude of the microcavities 305 may correspond to one or more pixel areas, and the pixel area may correspond to an area for displaying an image.

A common electrode 270 and a lower insulating layer 350 are disposed on the upper alignment layer 21. The common electrode 270 receives the common voltage, generates an electric field along with the pixel electrode 191 to which the data voltage is applied, and determines orientations of the liquid crystal molecules 310 disposed in the microcavity 305 between the two electrodes. The common electrode 270 forms a capacitor along with the pixel electrode 191 to maintain an applied voltage even after the thin film transistor is turned off. The lower insulating layer 350 may be made of silicon nitride or silicon oxide. Referring to FIG. 3, the common electrode 270 and the lower insulating layer 350 may be disposed in both of the display area DA and the peripheral area PA, and may be included as a layer of the blocking layer BL.

Although an example where the common electrode 270 is formed above the microcavity 305 is illustrated, in another exemplary embodiment, the common electrode 270 may be formed below the microcavity 305 such that liquid crystals are driven according to a coplanar electrode (CE) mode.

A roof layer 360 is disposed on the lower insulating layer 350. The roof layer 360 serves to support the microcavity 305 that is formed between the pixel electrode 191 and the common electrode 270. Referring to FIG. 3, the roof layer 360 is also disposed in the peripheral area PA and forms one layer of the blocking layer BL in the gate driver 500.

The roof layer 360 may be made of a photoresist or other organic material. The roof layer 360 may be formed as a color filter. In this case, as shown in FIG. 9, color filters of respective different colors may overlap a partition wall portion 320. The partition wall portion 320 is disposed between microcavities 305 that are adjacent in the horizontal direction. The partition wall portion 320 is a portion that fills a separated space between the microcavities 305 adjacent in the horizontal direction. The partition wall portion 320 may be formed along a direction in which the data line 171 extends, and may partition or define the microcavities 305. The roof layer 360 may be made of an inorganic material.

An upper insulating layer 370 is disposed on the roof layer 360. The upper insulating layer 370 may be made of silicon nitride or silicon oxide. Referring to FIG. 3, the upper insulating layer 370 may be disposed in both of the display area DA and the peripheral area PA. In the peripheral area PA, the upper insulating layer 370 may be included as a layer of the blocking layer BL to protect the contact holes of the gate driver 500 from an external environment.

A capping layer 390 is disposed on the upper insulating layer 370. The capping layer 390 is also disposed in an injection area 307FP, and covers the injection hole 307 of the microcavity 305 that is exposed by the injection area 307FP. The capping layer 390 may be made of an organic or inorganic material. In FIG. 8, the injection area 307FP is illustrated such that the liquid crystal material has been removed, but remaining liquid crystal material after being injected into the microcavity 305 may exist in the injection area 307FP. In this case, since the capping layer 390 may contact and contaminate the liquid crystal material, the capping layer 390 may be made of a material, such as parylene, that does not react with the liquid crystal material.

A barrier layer 395 may be formed on the capping layer 390. The barrier layer 395 may be made of silicon nitride and the like, and may prevent permeation of external moisture, oxygen, etc.

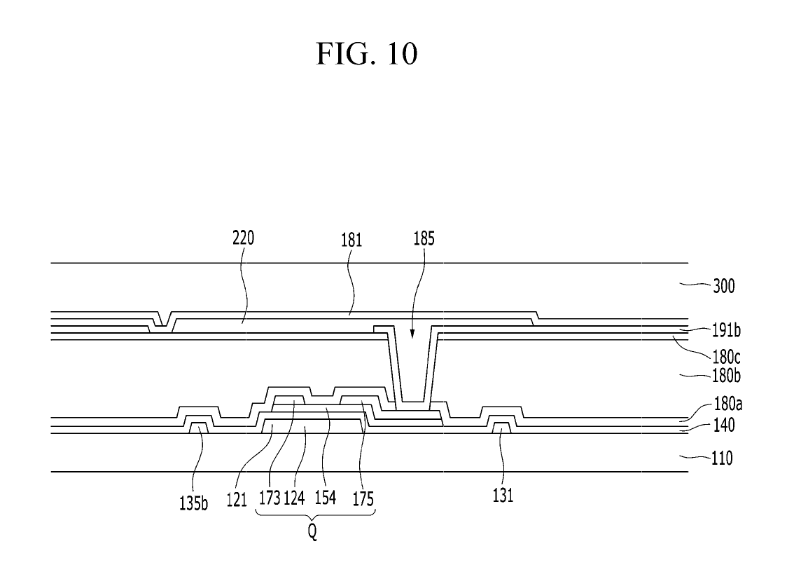

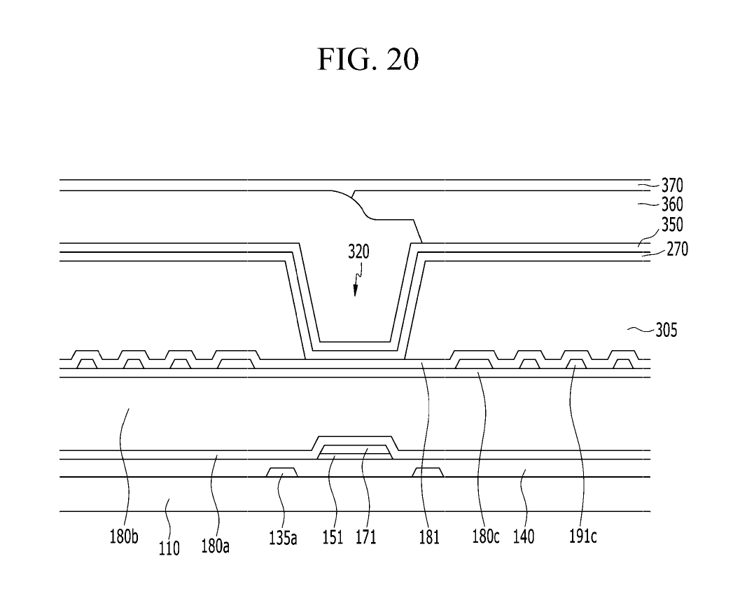

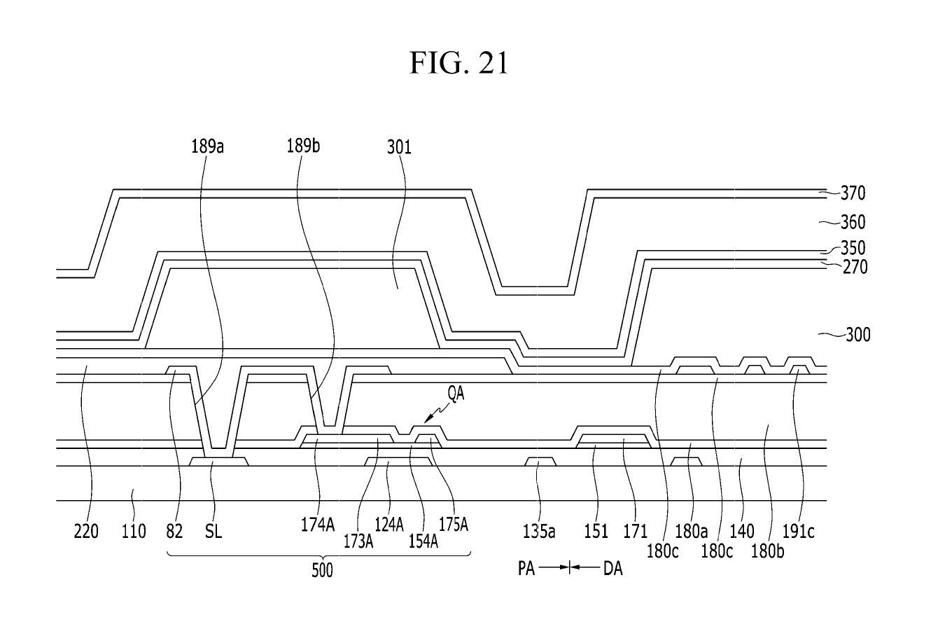

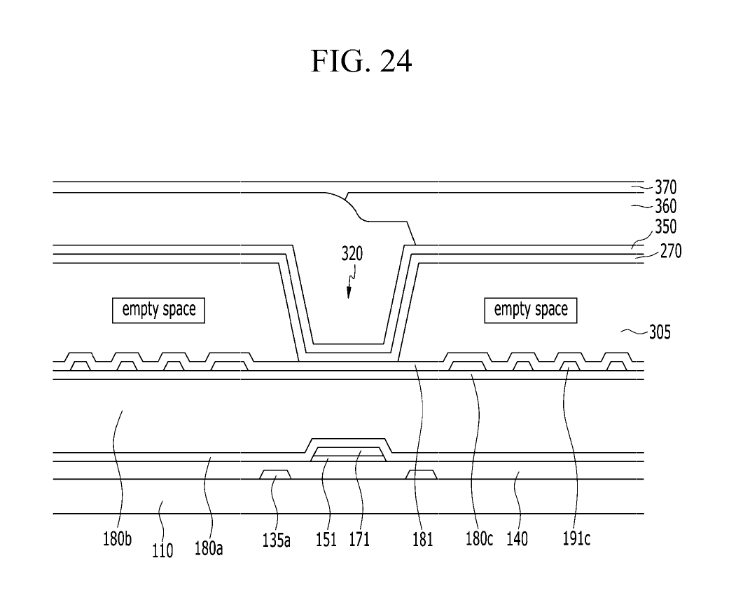

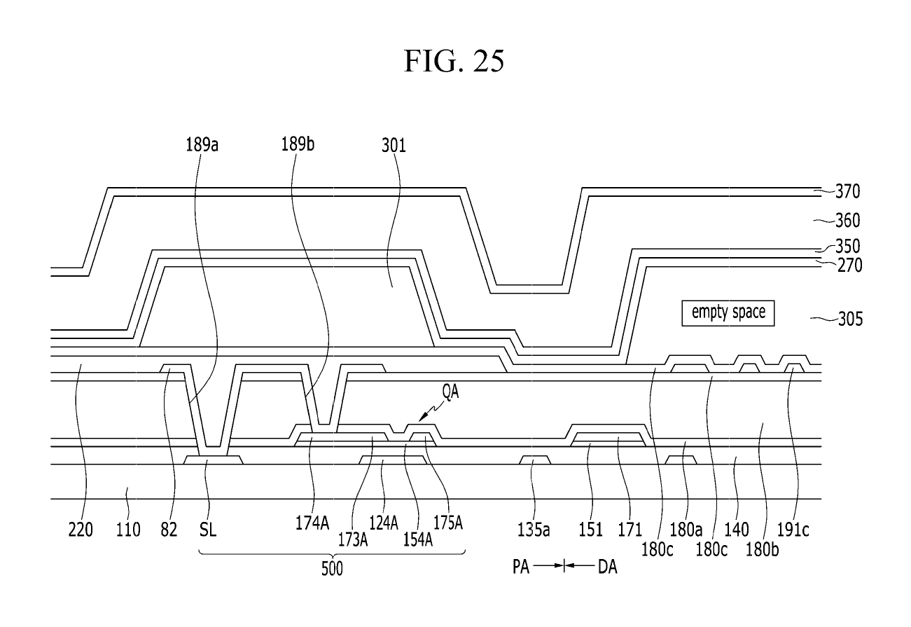

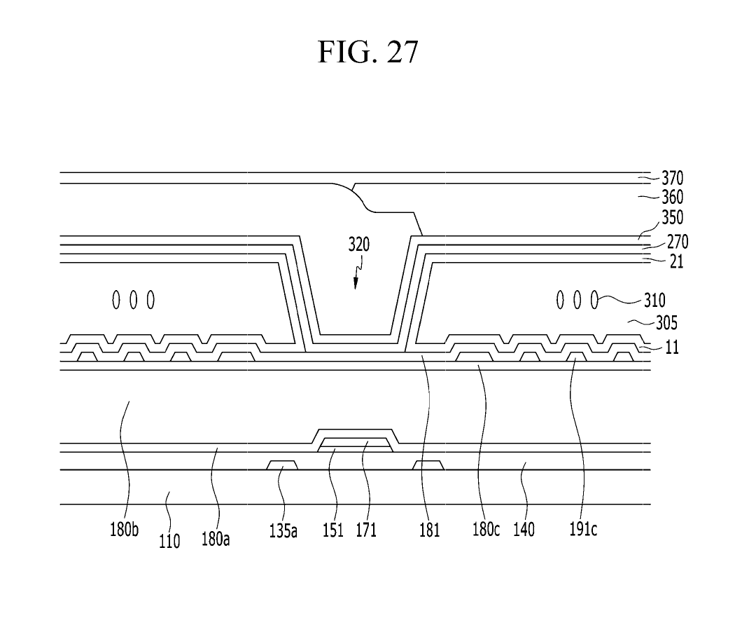

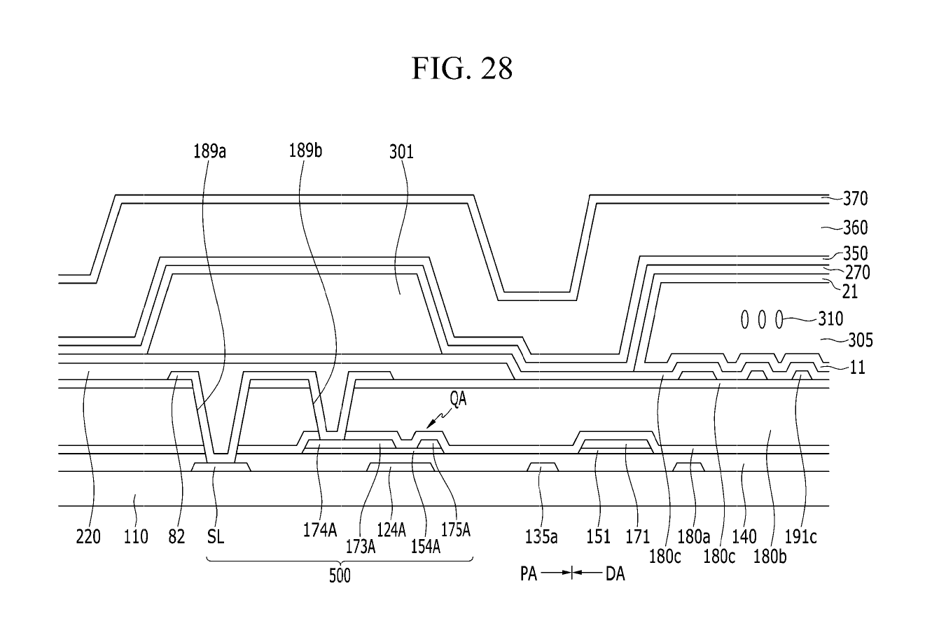

An exemplary embodiment of a manufacturing method of the aforementioned LCD will now be described with reference to FIGS. 10 to 28. The exemplary embodiment to be described below is an exemplary embodiment of the manufacturing method, and it may be modified in different forms, processes, and sequences.

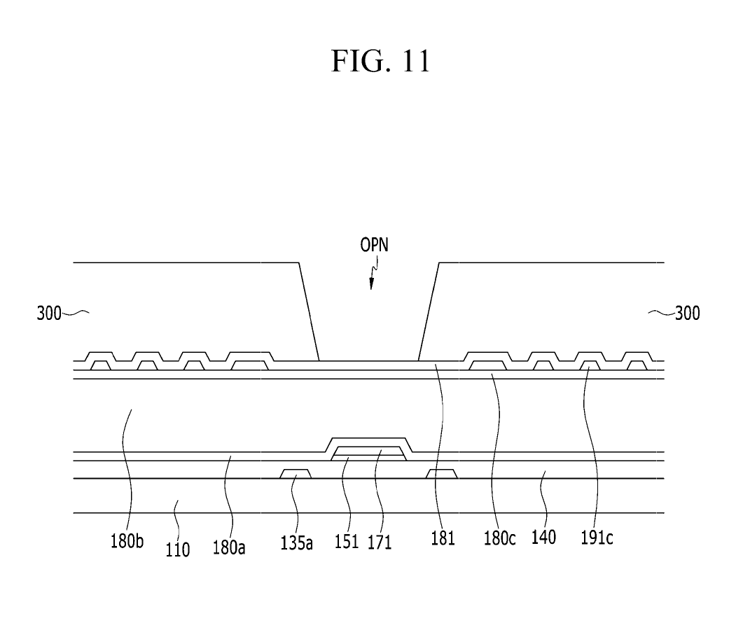

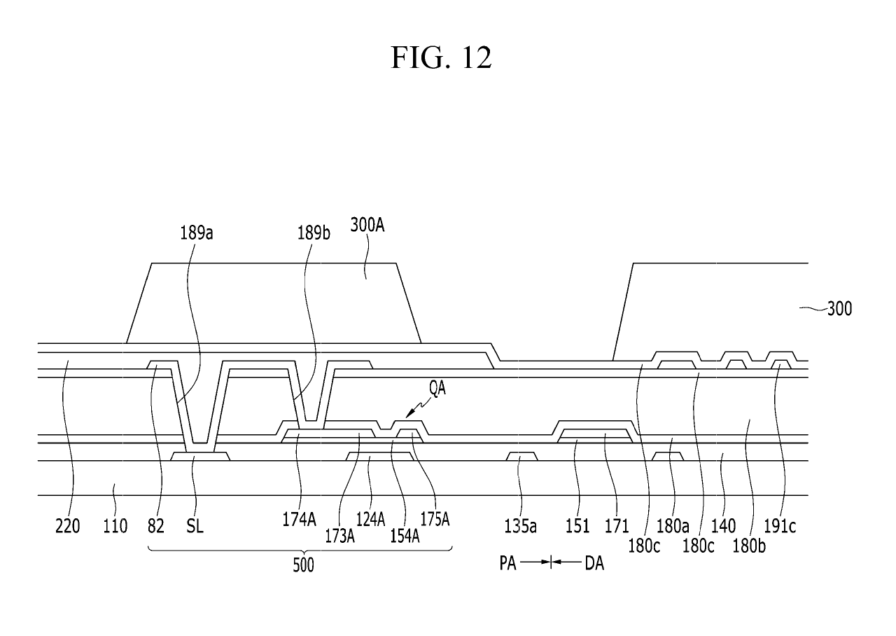

FIGS. 10 to 28 are process cross-sectional views illustrating a manufacturing method of an LCD, according to the exemplary embodiment of the present disclosure. FIGS. 10, 13, 16, 19, 22, 23 and 26 sequentially show a cross-section of FIG. 3 taken along the line II-II, and FIGS. 11, 14, 17, 20, 24 and 27 sequentially show a cross-section of FIG. 7 taken along the line III-III. FIGS. 12, 15, 18, 21, 25 and 28 show a process of laminating a blocking film and the like in the gate driver of FIG. 3.

Referring to FIGS. 7, 10, 11, and 12, to form a generally-known thin film transistor Q on a substrate 110, a gate line 121 is formed to extend in a horizontal direction, a gate insulating layer 140 is formed on the gate line 121, semiconductor layers 151 and 154 are formed on the gate insulating layer 140, and a source electrode 173 and a drain electrode 175 are formed. In this case, a signal line SL of the gate driver 500 and a thin film transistor QA of a driving circuit are formed together. A first interlayer insulating layer 180a is formed on data conductors 171, 173, and 175 including a source electrode 173, and a first passivation layer 180a is formed on an exposed portion of the semiconductor layer 154. The first passivation layer 180a is also formed on the thin film transistor QA.

Second and third passivation layers 180b and 180c are formed on the first passivation layer 180a, and a contact hole 185 is formed to penetrate the second and third passivation layers 180b and 180c. Next, a pixel electrode 191 is formed on the third passivation layer 180c, and the pixel electrode 191 is electrically and physically connected to the drain electrode 175 via the contact hole 185. When forming the contact hole 185 of a display area, first and second contact holes 189a and 189b are formed in the gate driver 500. When forming the pixel electrode 191, a bridge 82 is formed to electrically couple the signal line SL and the driving circuit. The pixel electrode 191 and the bridge 82 may be formed simultaneously by depositing and then patterning a conductive material such as ITO, IZO, etc.

A light blocking member 220 is formed on the pixel electrode 191 or the third passivation layer 180c. The light blocking member 220 is formed along a direction in which the gate line 121 extends. The light blocking member 220 is made of a material that can block light. The light blocking member 220 is also formed in the gate driver 500, and may be formed in an entire peripheral area PA. An insulating layer 181 is formed on the light blocking member 220, and the insulating layer 181 is formed to cover the light blocking member 220 and to be extended above the pixel electrode 191. The insulating layer 181 may be omitted.

Next, a sacrificial layer 300 is formed on the insulating layer 181. An open portion OPN is formed in the sacrificial layer 300 along a direction parallel to the data line 171. In a subsequent process, the open portion OPN is filled with a roof layer 360, thereby forming a partition wall portion PWP. The sacrificial layer 300 may be formed by applying and then patterning a photoresist or other organic material. A sacrificial layer 300A is also formed on the contact holes 189a and 189b of the gate driver 500. In other words, the organic material coated on the contact holes 189a and 189b is not removed and forms the sacrificial layer 300A. Subsequently, the sacrificial layer 300A becomes a base layer 301 of the blocking layer BL, or is removed to form a microcavity. In the latter case, a liquid crystal layer is formed in the microcavity, thereby forming the base layer 301 of the blocking layer BL.

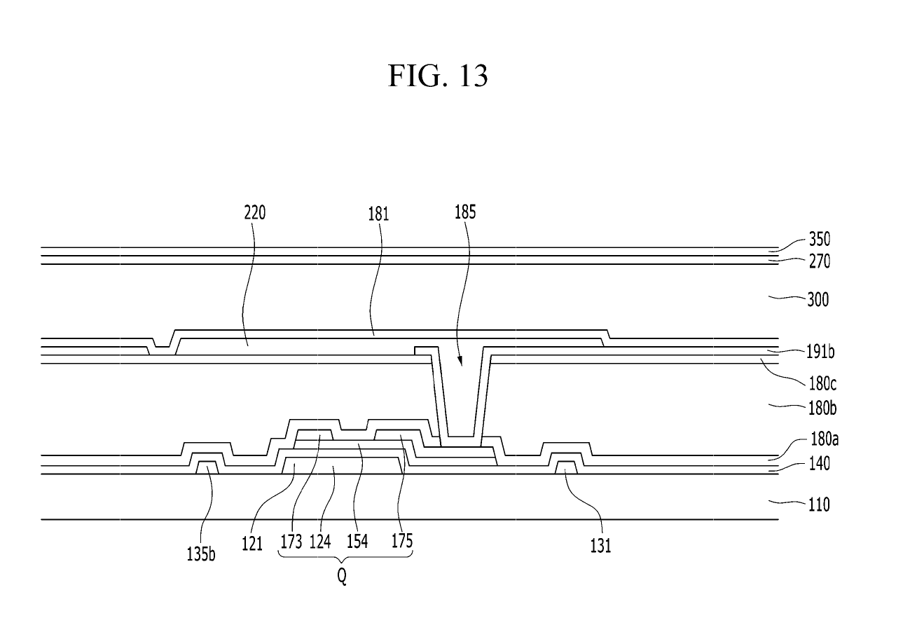

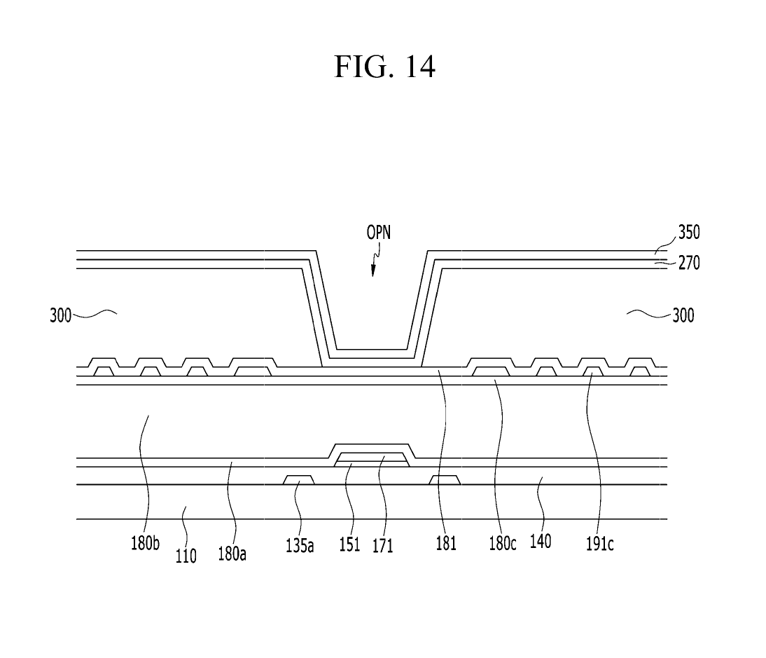

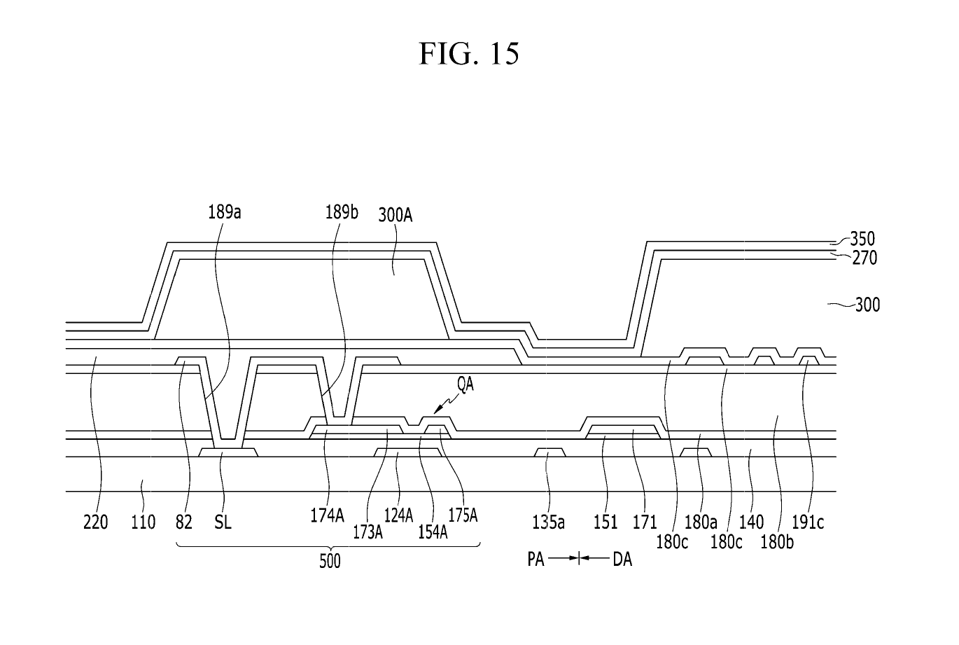

Referring to FIGS. 13, 14, and 15, a common electrode 270 and a lower insulating layer 350 are sequentially formed on the sacrificial layers 300 and 300A. As shown in FIG. 14, the common electrode 270 and the lower insulating layer 350 may cover the open portion OPN. As shown in FIG. 15, the common electrode 270 is formed in the display area DA to be extended to the gate driver 500, but may be formed to be disconnected between the display area DA and the gate driver 500.

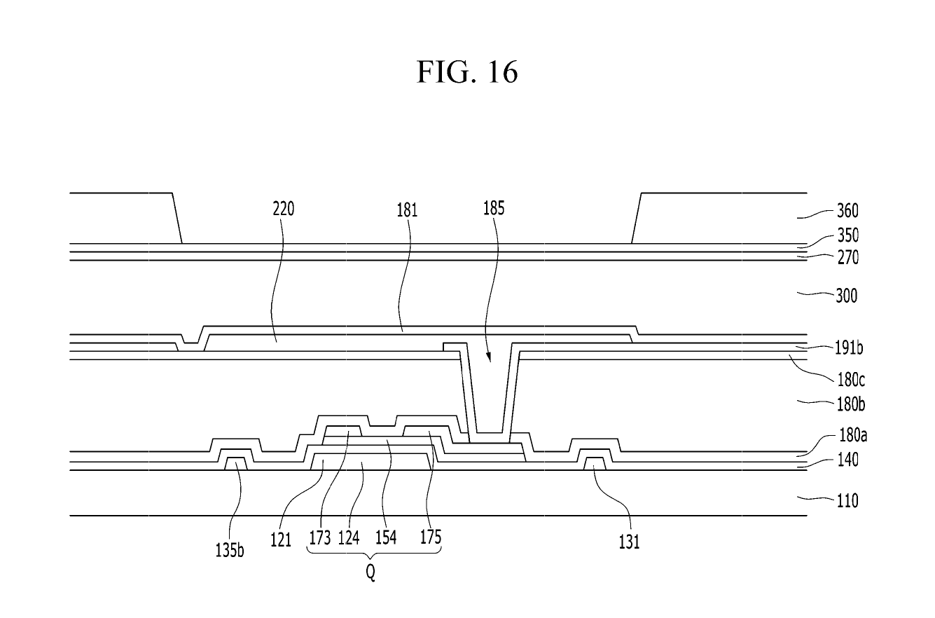

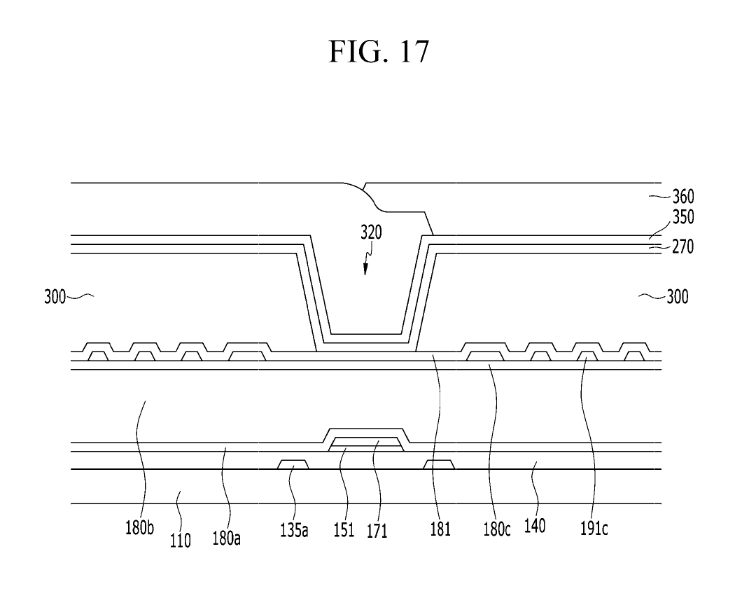

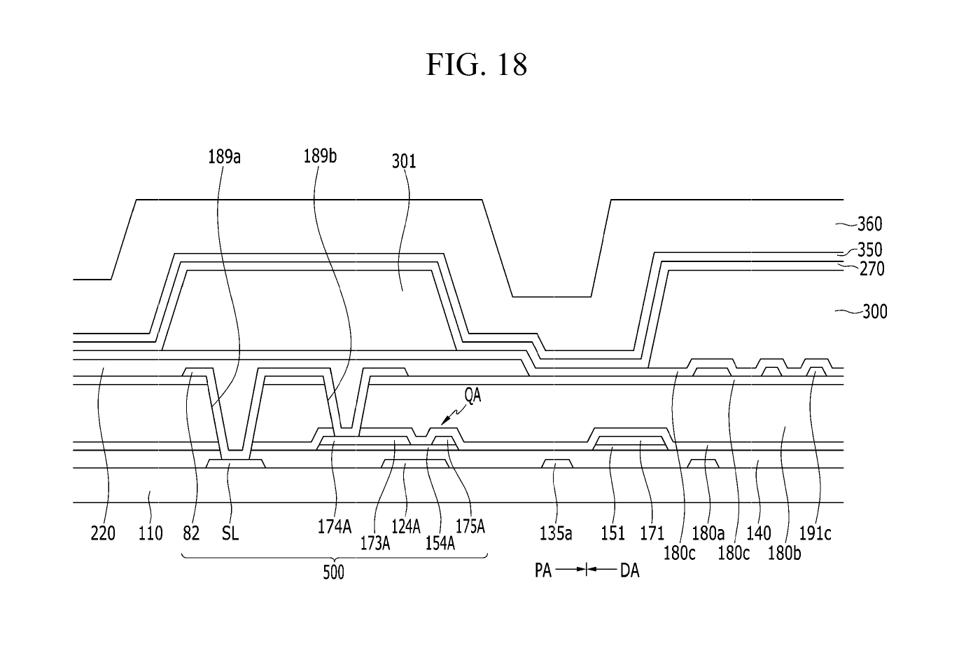

Referring to FIGS. 16, 17, and 18, a roof layer 360 is formed on the lower insulating layer 350. The roof layer 360 may be removed by a patterning or exposure/developing process from a region corresponding to the light blocking member 220 that is disposed between the pixel areas vertically adjacent to each other. As shown in FIG. 16, the roof layer 360 exposes the lower insulating layer 350 in the region corresponding to the light blocking member 220. As shown in FIG. 17, the roof layer 360 forms the partition wall portion 320 while filling the open portion OPN of the vertical light blocking member 220b. The roof layer 360 may be formed as a color filter. As shown in FIG. 18, the roof layer 360 is also formed on the lower insulating layer 350, and forms, as shown in FIG. 3, one layer of the blocking layer BL. When the liquid crystal layer is formed as the base layer 301 of the blocking layer BL, the sacrificial layer 300A needs to be removed, in which case, the roof layer 360 formed on the sacrificial layer 300A is partially removed.

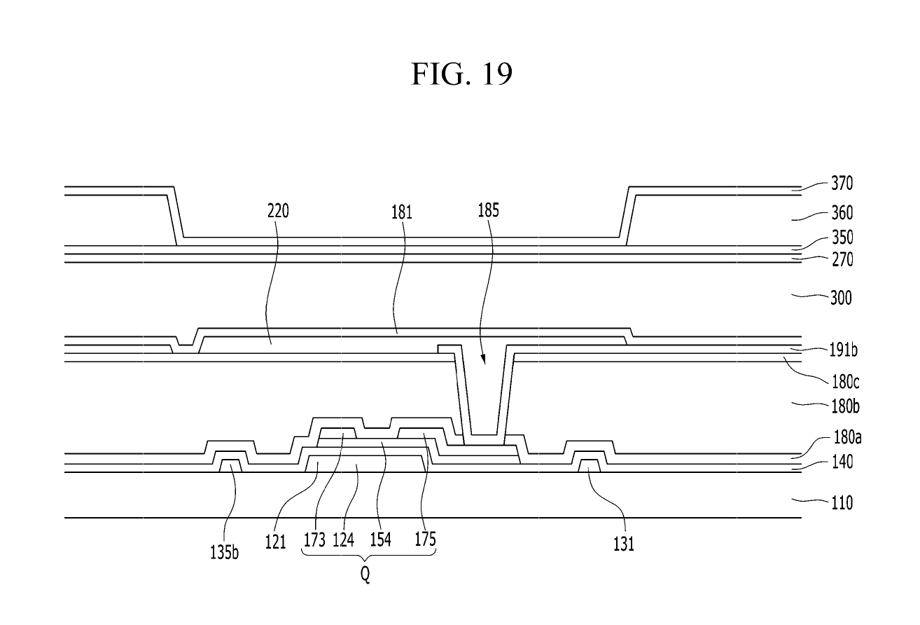

Referring to FIGS. 19, 20, and 21, an upper insulating layer 370 is formed to cover on top of the roof layer 360 and the exposed lower insulating layer 350. The upper insulating layer 370 of the display area DA is formed to be extended to the gate driver 500 of the peripheral area PA, thereby forming one layer of the blocking layer BL.

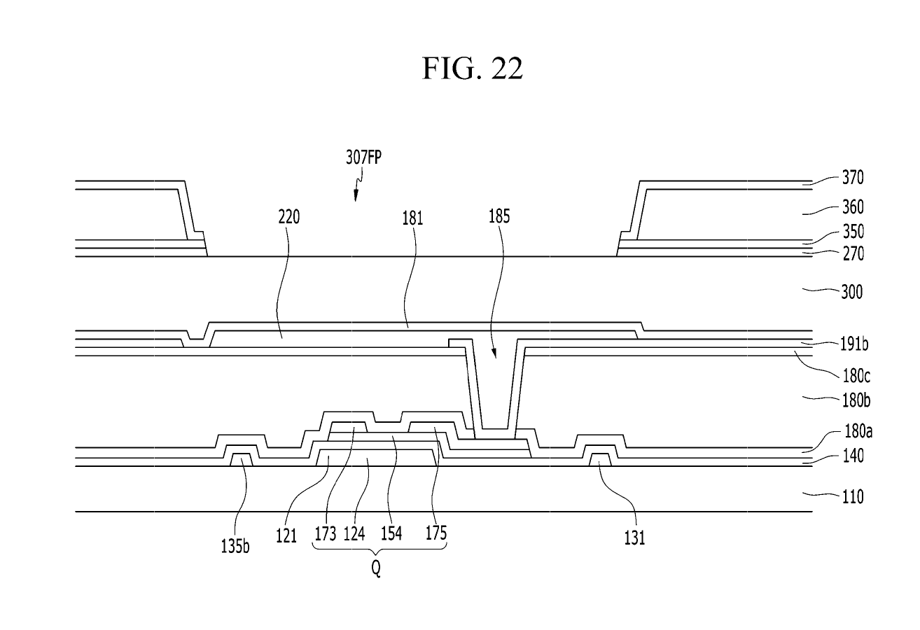

Referring to FIG. 22, an injection area 307FP is formed by etching the upper insulating layer 370, the lower insulating layer 350, and the common electrode 270 to partially remove the upper insulating layer 370, the lower insulating layer 350, and common electrode 270. The sacrificial layer 300 is exposed to the outside of the injection area 307FP. The upper insulating layer 370 may cover, as illustrated, a lateral surface of the roof layer 360, but it is not limited thereto and the upper insulating layer 370 covering the lateral surface of the roof layer 360 may be removed to expose the lateral surface of the roof layer 360 to the outside. When the liquid crystal layer is formed as the base layer 301 of the blocking layer BL, the upper insulating layer 370, the lower insulating layer 350, and the common electrode 270 formed on the sacrificial layer 300A may be partially etched, thereby exposing the sacrificial layer 300A to the outside. However, when the sacrificial layer 300A is formed as the base layer 301 of the blocking layer BL, the sacrificial layer 300A should not be removed, so the layers formed on the sacrificial layer 300A do not need to be partially etched.

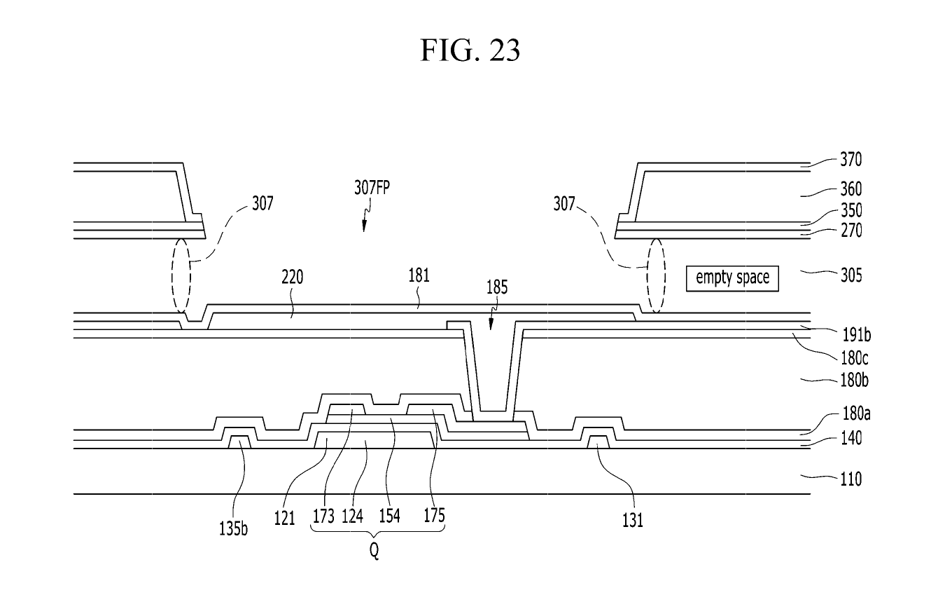

Referring to FIGS. 23, 24, and 25, an ashing process or a wet etching process is used to remove the sacrificial layer 300 through the injection area 307FP and form a microcavity 305 including an injection hole 307. The microcavity 305 is empty because the sacrificial layer 300 is removed. When the liquid crystal layer is formed as the base layer 301 of the blocking layer BL, the sacrificial layer 300A may be removed when removing the sacrificial layer 300, such that the microcavity including the injection hole is formed even in the gate driver 500.

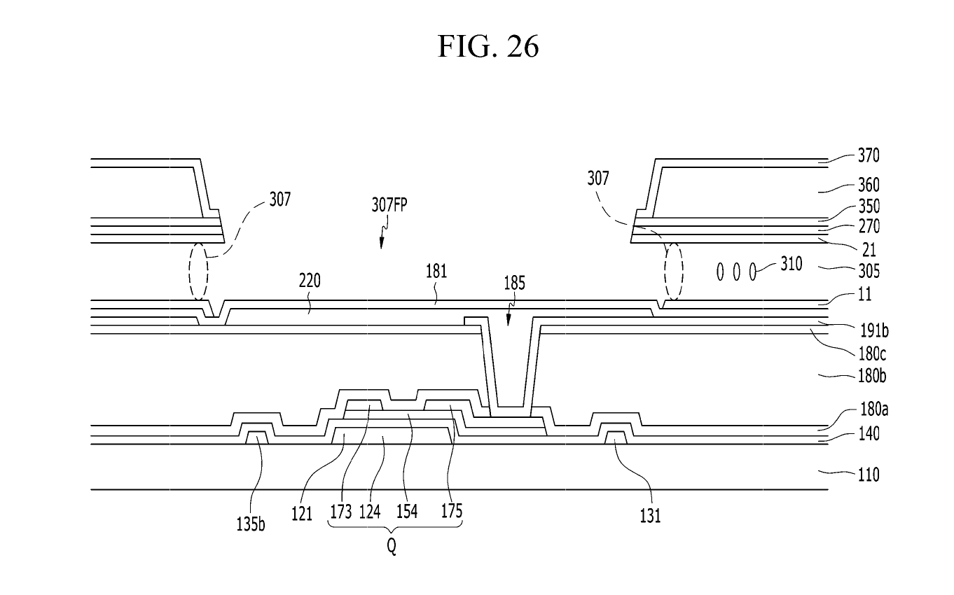

Referring to FIGS. 26, 27, and 28, after an aligning material is injected via the injection hole 307, a bake process is performed to form alignment layers 11 and 21 on the pixel electrode 191 and the common electrode 270. Next, a liquid crystal material including the liquid crystal molecules 310 is injected into the microcavity 305 via the injection hole 307 using an inkjet method and the like. When the liquid crystal layer is formed as the base layer 301 of the blocking layer BL, the same process is applied to the gate driver 500. Next, a capping layer 390 and a barrier layer 395 are formed to cover the injection hole 307 and the injection area 307FP on top of the upper insulating layer 370, thereby manufacturing an LCD as illustrated in FIGS. 3 and 7. The blocking layer BL formed on the contact holes of the gate driver 500 may be formed together when forming the respective layers of the display area DA to eliminate additional process or mask for forming the blocking layer BL.

While the present disclosure has been described in connection with exemplary embodiments, it is to be understood that the present disclosure is not limited to the disclosed exemplary embodiments, but, on the contrary, is intended to cover various modifications and equivalent arrangements included within the spirit and scope of the present disclosure.

What is claimed is:

1. A liquid crystal display (LCD) comprising:
a substrate including a display area and a peripheral area;
a thin film transistor disposed on the display area of the substrate;
a pixel electrode connected to the thin film transistor;
a liquid crystal layer disposed inside a microcavity on the pixel electrode;
a roof layer disposed on the microcavity;
a gate driver integrated on the peripheral area of the substrate and including a plurality of signal lines and a plurality of stages connected to the plurality of signal lines via contact holes; and
a blocking layer comprising a base layer disposed on the contact holes and a first inorganic layer disposed on the base layer.

2. The LCD of claim 1, wherein:
the base layer is an organic layer or a liquid crystal layer.

3. The LCD of claim 2, further comprising:
a lower insulating layer disposed between the microcavity and the roof layer in the display area,
wherein the first inorganic layer of the blocking layer is formed as a same layer as the lower insulating layer.

4. The LCD of claim 3, wherein:
the blocking layer further comprise a roof layer disposed on the first inorganic layer, and
the roof layer of the blocking layer is formed as a same layer as the roof layer of the display area.

5. The LCD of claim 4, further comprising:
an upper insulating layer disposed on the roof layer in the display area,
wherein the blocking layer further comprises a second inorganic layer that is disposed on the roof layer and is formed as a same layer as the upper insulating layer.

6. The LCD of claim 1, further comprising:
a common electrode disposed between the microcavity and the roof layer in the display area,
wherein the blocking layer further comprises a conductive layer that is formed between the base layer and the inorganic layer and as a same layer as the common electrode.

7. The LCD of claim 1, wherein:
the blocking layer is disposed to overlap and cover the contact holes.

8. The LCD of claim 1, wherein:
the blocking layer is formed to entirely cover the gate driver.

9. The LCD of claim 1, wherein:
the blocking layer is formed to partially cover the gate driver.

10. The LCD of claim 1, wherein:
the base layer of the blocking layer has a substantially same size as the microcavity of the display area.

11. The LCD of claim 1, wherein:
the base layer of the blocking layer is larger in size than the microcavity of the display area.

12. A method for manufacturing an LCD comprising:
forming a thin film transistor in a display area of a substrate;
forming a gate driver including a signal line of a gate driver and a stage in a peripheral area of the substrate;
forming at least one passivation layer on the thin film transistor, the signal line of the gate driver, and the stage;
forming, in the display area, a pixel electrode connected to the thin film transistor via a contact hole formed in the at least one passivation layer;
forming, in the peripheral area, a bridge for interconnecting the signal line and the stage via contact holes formed in the at least one passivation layer;
forming a first sacrificial layer on the pixel electrode of the display area and a second sacrificial layer on the contact holes of the peripheral area;
forming a lower insulating layer on the first sacrificial layer and the second sacrificial layer; and
forming, on the lower insulating layer, a roof layer overlapping the first sacrificial layer and the second sacrificial layer.

13. The method of claim 12, further comprising:
forming, on the roof layer, an upper insulating layer overlapping the first sacrificial layer and the second sacrificial layer.

14. The method of claim 12, further comprising:
forming a common electrode on the first sacrificial layer and the second sacrificial layer.

15. The method of claim 12, further comprising:
removing the first sacrificial layer to form a microcavity; and
forming a liquid crystal layer inside the microcavity in the display area.

16. The method of claim 13, further comprising:
simultaneously removing the first sacrificial layer and the second sacrificial layer to form a microcavity; and
forming a liquid crystal layer inside the microcavity formed in the peripheral area.

17. The method of claim 13, wherein:
removing the first sacrificial layer without removing the second sacrificial layer.
